(19) United States
(12) Patent Application Publication
(10) Pub. No.: US 2006/0234526 A1
(43) Pub. Date: Oct. 19, 2006

(54) Automation system

(75) Inventors: Kai Garrels, Mannheim (DE); Richard Steigmann, Gerolsheim (DE); Ralph Schelling, Ludwigshafen (DE)

Correspondence Address: BUCHANAN, INGERSOLL & ROONEY PC, POST OFFICE BOX 1404, ALEXANDRIA, VA, 22313-1404, US

(73) Assignee: ABB Patent GmbH, Ladenburg (DE)

(21) Appl. No.: 11/393,847

(22) Filed: Mar. 31, 2006

(30) Foreign Application Priority Data
Apr. 15, 2005 (DE) 102005017172.3

(51) Int. Cl. H05K 1/00

(52) U.S. Cl. 439/76.1

(57) ABSTRACT

An automation system is proposed, having a central control module and digital input modules and/or analogue input modules and/or digital output modules and/or analogue output modules and/or I/O modules, which modules are connected to one another via an internal bus system, and which are connected via lines to digital sensors and/or analogue sensors and/or digital actuators and/or analogue actuators. The automation system has at least one base station module which communicates by radio via at least one antenna with wire-free sensors and/or actuators and/or I/O appliances, which each have an antenna, of a machine or installation.

The invention relates to an automation system according to the precharacterizing clause of claim 1. By way of example, the invention may be used in manufacturing installations with sensors and/or actuators which do not use wires for power supply and communication purposes.

Proximity switches/proximity sensors, temperature measurement sensors, pressure measurement sensors, current measurement sensors or voltage measurement sensors, and/or micromechanical, piezoelectric, electrochemical, magnetostrictive, electrostatic or electromagnetic actuators may be used as sensors and actuators, respectively.

Apart being used for industrial robots, automatic production machines and automatic manufacturing machines, the invention can also be used for open-loop/closed-loop control systems, remote control systems, protection, safety and security systems (for example in the case of open-air or indoor switchgear assemblies), alarm systems, status monitoring systems, in robot engineering, or in an entirely general form for machines/machine systems.

WO 98/017797 and EP 0 910 819 B1 disclose a process automation system in which terminals in a control and monitoring level and- automation devices in an automation level linked to a process communicate with a host computer via transmission/reception devices and a data transmission medium (radio link, telecommunications network). This host computer may be in the form of a supercomputer in a computer centre, and may control further process automation systems.

WO 99/66473 discloses an automation system having a control apparatus for controlling a processing apparatus, in particular a manufacturing apparatus, with at least one sensor being provided for transmission of sensor data from the processing apparatus to the control apparatus. In order to reduce the sensor installation complexity, it is proposed that the sensors have a radio transmission apparatus and a radio receiving apparatus, which are intended for wire-free transmission of the sensor data to the receiving apparatus, which is connected to the control apparatus.

DE 103 47 584 A1 proposes a system having a large number of sensors and/or actuators, which are fed without the use of wires, as nodes, and a base station, which is installed in a machine or installation, such as an industrial robot, an automatic production machine or automatic manufacturing machine, with communication taking place by radio, without the use of wires, between the sensors and/or actuators on the one hand and the base station that is connected to the automation appliance on the other hand. The base station is connected via electrical lines to the automation appliance in such a way that a separate line is associated with each wire-free sensor and/or actuator. In this case, the signals can be transmitted via the electrical lines in the form of standardized DC signals. The base station may be in the form of a base station plug-in card with a standardized plug connector, which can be plugged onto an I/O card in the automation appliance.

DE 10032 868 A1 proposes a system, in particular an automation system, using a control system and a plurality of actuators and sensors, in which wire-free communication takes place, in order to transmit sensor data, between a base station which is connected to the control system and has a radio receiver, and the sensor which has radio transmitters, and in which the base station is combined with at least one actuator to form an actuator/base station. The actuator/base station may have a processing unit with an integrated input/output unit.

The invention is based on the object of specifying an automation system of the type mentioned initially, which can be configured in a simple manner.

According to the invention, this object is achieved, in conjunction with the features of the precharacterizing clause, by the features specified in the characterizing part of claim 1.

The advantages which can be achieved by the invention are, in particular, that the proposed automation system can be configured both for a relatively small number and for a relatively large number of sensors and/or actuators. Subsequent extensions to the automation system with additional sensors and/or actuators and/or additional cells are possible without any problems, and the same also applies, of course, to reductions to the automation system by the removal of originally provided and operated sensors and/or actuators and/or cells. There is no need for any additional components for the connection between the automation system and the base station, such as couplers or fieldbus connectors.

Further advantages will become evident from the following description.

Advantageous refinements of the invention are characterized in the dependent claims.

The invention will be explained in the following text with reference to the exemplary embodiments which are illustrated in the drawing, in which:

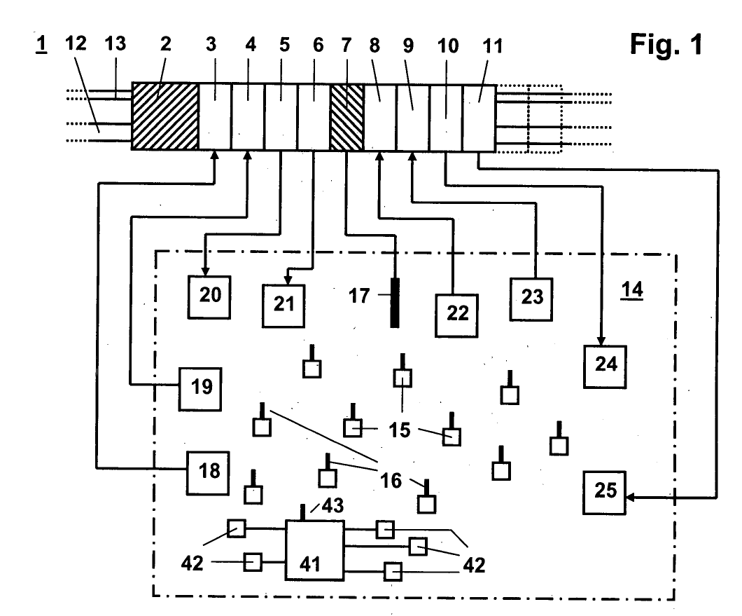

FIG. 1 shows an automation system for a machine or installation, and

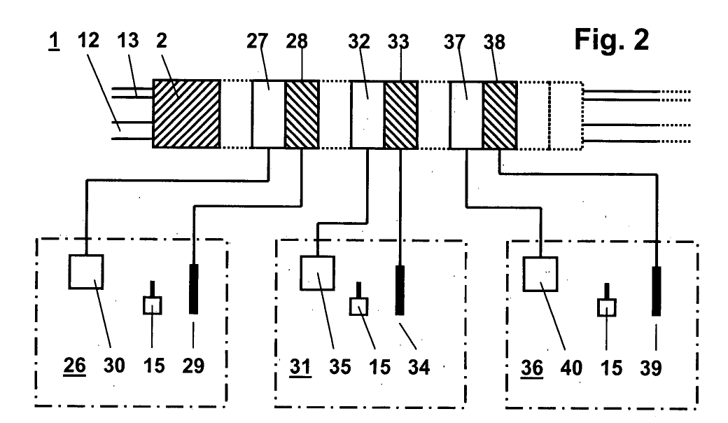

FIG. 2 shows an automation system having a plurality of base stations for an installation having a plurality of cells.

FIG. 1 shows an automation system 1 for a machine or installation 14. The machine or installation 14 has:
A large number of wire-free sensors and/or actuators 15, which each have an antenna 16 and communicate by radio with a base station module 7, for which purpose the latter is connected to an antenna 17,
If required, a plurality of digital sensors 18 and 22, which are connected via lines to digital input modules 3 and 8, respectively, of the automation system 1,
If required, a plurality of analogue sensors 19 and 23, which are connected via lines to analogue input modules 4 and 9, respectively, of the automation system 1,
If required, a plurality of digital actuators 20 and 24, which are connected via lines to digital output modules 5 and 10, respectively, of the automation system 1,
If required, a plurality of analogue actuators 21 and 25, which are connected via lines to analogue output modules 6 and 11, respectively, of the automation system 1, and
If required, at least one wire-free I/O appliance (input/output) 41, which is connected via lines to sensors and/or actuators 42 (digital or analogue) and has an antenna 43 via which it communicates or they communicate by radio with the base station module 7.

Two antennas (transmitting antenna, receiving antenna) may, of course, also be used instead of one antenna 17. As an alternative to separate input modules and separate output modules, it is also possible to use (analogue or digital) I/O modules (input/output) . The embodiment with a wire-free I/O appliance 41 is particularly advantageous when actuators 42 which draw their energy via the I/O appliance are connected to the I/O appliance 41.

In addition to the input modules 3, 4, 8, 9 and output modules 5, 6, 10, 11 mentioned above as well as the base station module 7, the automation system 1 has a higher-level central control module (programmable logic controller PLC) 2. All of the modules 2-11 may, for example, be mechanically mounted on a top-hat profile rail 12, and arranged in a row. The communication between the modules 2-11 takes place via an internal bus system 13, with the electrical connection between each module and this internal bus system 13 being made, for example, automatically by means of plug-in contacts when latching the respective module onto the top-hat profile rail 12. Alternatively, the said electrical connection can also be made, for example, by latching of the modules. An SPI (serial peripheral interface) interface may be used as the internal bus system.

As already indicated by the further modules represented by dashed lines in FIG. 1, there are no difficulties whatsoever in fitting further modules to the automation system 1. In this case, it is irrelevant how many digital input modules, analogue input modules, digital output modules and analogue output modules are fitted to the automation system. The number of these modules illustrated in FIG. 1 is only by way of example.

In general, with regard to the system: the wire-free communication by radio between the sensors and/or actuators 15 (as well as wire-free I/O appliances 41) on the one hand and the automation system 1 on the other hand takes place using the base station module 7. The expression communication means, in particular, sensor signals (data) being passed on from the wire-free sensors (as well as wire-free I/O appliances 41) to the automation system 1, and instructions being emitted from the automation system 1 to the wire-free actuators (as well as wire-free I/O appliances 41). Generally known radio methods, such as CDMA or TDMA, may be used in order to separate the individual radio links from one another and in order to prevent disturbing interference between the individual communication paths.

The base station module 7 preferably has a radio transmitter and/or a radio receiver or, alternatively, a combined transmitting/receiving device, which emits and receives radio signals, with at least one antenna 17 being provided, of course. The wire-free communication between the base station module 7 and the individual wire-free sensors and/or wire-free actuators 15 preferably takes place via 2-way radio links. Each wire-free sensor and actuator (as well as each wire-free I/O appliance 41) is for this purpose equipped with a radio transmitter and/or a radio receiver, or combined transmitting/receiving device, which emits and receives radio signals. By way of example, the wire-free sensors emit sensor signals, that is to say radio signals, relating to the instantaneous state/switching state, and receive parameter sets by radio, such as predetermined sensor switching thresholds or switching hystereses, and/or predetermined correction factors for various materials to be identified, in the case of proximity sensors.

The wire-free actuators (as well as wire-free I/O appliances 41) receive parameter sets and/or control instructions for control purposes, for carrying out specific operations, and emit feedback signals, for example radio signals relating to instantaneous actuator information such as the feedback message “desired operation carried out successfully/unsuccessfully” or, in general, the feedback message relating to the instantaneous actuator position, to the control system. The radio signals to all of the wire-free sensors and/or actuators 15 (as well as wire-free I/O appliances 41) and from all of the wire-free sensors and/or actuators (as well as wire-free I/O appliances 41) are emitted and received by the base station module 7 as the central transmitting/receiving device in the automation system.

In a simpler embodiment, which is suitable only for wire-free 1-way communication with sensors, the base station module 7 has only one radio receiver, while each wire-free sensor is provided with only one radio transmitter. In this embodiment, it is possible for the detected sensor data to be transmitted as wire-free sensor signals to the base station module 7.

In a simpler embodiment, which is suitable only for wire-free 1-way communication with actuators, the base station module 7 has only one radio transmitter, while each wire-free actuator (as well as each wire-free I/O appliance 41) is provided with only one radio receiver. In this embodiment, it is possible to transmit the necessary control instructions and parameter sets to the actuators without the use of wires.

FIG. 2 shows an automation system having a plurality of base stations for an installation having a plurality of cells. In this embodiment, the automation system 1 has a plurality of associated cells 26, 31 and 36, which respectively have digital sensors and/or analogue sensors and/or digital actuators and/or analogue actuators 30, 35 and 40, as well as a large number of wire-free sensors and/or actuators 15 (as well as wire-free I/O appliances 41)—in each case with an antenna 16 (or 43). In a corresponding manner to this, the automation system 1 has its own base station module 28, 33 or 38, respectively, which communicates via a respective antenna 29, 34 or 39, which is associated with the respective cell 26, 31 or 36, with the sensors and/or actuators 15 (as well as the wire-free I/O appliances 41) in the cell. When using the TDMA method for radio transmission, the individual cells 26, 31, 36 are operated at different frequencies.

The automation system 1 has digital input modules and/or analogue input modules and/or digital output modules and/or analogue output modules 27, 32 and 37, respectively, which are connected via lines to the digital sensors and/or analogue sensors and/or digital actuators and/or analogue actuators 30, 35 and 40, respectively, in the individual cells 26, 31 and 36, respectively. The modules 27, 28, 32, 33, 37, 38 are in turn mounted together with the central control module 2 alongside one another on the top-hat profile rail 12, and are connected to one another via the internal bus system 13.

### LIST OF REFERENCE SYMBOLS

1 Automation system
2 High-level central control module
3 Digital input module
4 Analogue input module
5 Digital output module
6 Analogue output module
7 Base station module
8 Digital input module
9 Analogue input module
10 Digital output module
11 Analogue output module
12 Top-hat profile rail
13 Internal bus system
14 Machine or installation
15 Wire-free sensors and/or actuators
16 Antenna
17 Antenna
18 Digital sensor
19 Analogue sensor
20 Digital actuator
21 Analogue actuator
22 Digital sensor
23 Analogue sensor
24 Digital actuator
25 Analogue actuator
26 Cell
27 Digital input module and/or analogue input module and/or digital output module and/or analogue output module
28 Base station module
29 Antenna
30 Digital sensor and/or analogue sensor and/or digital actuator and/or analogue actuator
31 Cell
32 Digital input module and/or analogue input module and/or digital output module and/or analogue output module
33 Base station module
34 Antenna
35 Digital sensor and/or analogue sensor and/or digital actuator and/or analogue actuator
36 Cell
37 Digital input module and/or analogue input module and/or digital output module and/or analogue output module
38 Base station module
39 Antenna
40 Digital sensor and/or analogue sensor and/or digital actuator and/or analogue actuator
41 Wire-free I/O appliance
42 Sensor or actuator
43 Antenna

1. Automation system having a central control module and digital input modules and/or analogue input modules and/or digital output modules and/or analogue output modules and/or I/O modules, which modules are connected to one another via and internal bus system, and which are connected via lines to digital sensors and/or digital actuators wherein the automation system has at least one base station module which communicates by radio via at least one antenna with wire-free sensors and/or actuators and/or I/O appliances, which each have an antenna, or a machine or installation.

2. Automation system according to claim 1, wherein a plurality of base station modules are provided and each communicate via their own antennas with wire-free sensors and/or actuators and/or I/O appliances which are associated with different cells.

3. Automation systems according to claim 1 wherein a wire-free I/O appliance is connected via lines to sensors and/or actuators.

4. Automation system according to claim 1, wherein the electrical connections between each module and the internal bus system are made automatically by latching the modules to one another.

5. Automation system according to claim 1, wherein the modules which are arranged alongside one another, are mounted on a top-hat profile raid.

6. Automation system according to claim 5, wherein the electrical connections between each module and the internal bus system are made automatically by means of plug-in contacts when latching the respective module onto the top-hat profile rail.
